(19) United States
(12) Patent Application Publication
(10) Pub. No.: US 2007/0087544 A1
(43) Pub. Date: Apr. 19, 2007

(54) Method for forming improved bump structure

(75) Inventors: Hsu-Liang Chang, Taoyuan (TW); Ching-Hua Chu, Kaohsiung City (TW)

Correspondence Address: BIRCH, STEWART, KOLASCH & BIRCH, LLP, PO BOX 747, 8110 GATEHOUSE RD, STE 500 EAST, FALLS CHURCH, VA, 22040-0747, US

(73) Assignee: TAIWAN SEMICONDUCTOR MANUFACTURING CO., LTD.

(21) Appl. No.: 11/252,764

(22) Filed: Oct. 19, 2005

(51) Int. Cl. H01L 21/44

(52) U.S. Cl. 438/612; 257/E23.021

(57) ABSTRACT

Methods for forming an improved bump structure on a semiconductor device are provided. In one embodiment, a substrate is provided having at least one contact pad formed thereon. A first passivation layer is formed over the substrate, the first passivation layer having at least one opening therein exposing a portion of the contact pad. A first patterned and etched conductive metal layer is formed on the contact pad and above a portion of the first passivation layer. A second patterned and etched passivation layer is formed above the first passivation layer and a portion of the first conductive metal layer, wherein a portion of the ends of the first conductive metal layer is wedged between the first and second passivation layers. A second conductive metal layer is formed above the second passivation layer and the first conductive metal layer. A patterned and etched photoresist layer is then formed over a portion of the second passivation layer, the photoresist layer having an opening overlying the contact pad, and a solder material is deposited in the opening to form a solder column. The photoresist layer is thereafter removed and the second conductive metal layer is etched to the second passivation layer by using the solder column as an etching mask. The solder column is then reflown to create a solder bump.

### BACKGROUND OF THE INVENTION

1. Field of the Invention

The present invention relates generally to flip chip packaging technology, and more particularly, to methods for forming improved bump structures.

2. Description of the Related Art

Faster, reliable, and higher-density circuits at lower costs are the goals for integrated circuit (IC) packaging. Conventional wirebond technology, the most common method for electrically connecting aluminum bonding pads on a chip surface to the package inner lead terminals on the lead-frame or substrate has proven to be low cost and reliable. But for the future, packaging goals will be met by increasing the density of chips and reducing the number of internal interconnections. Packages with fewer interconnecting links lower potential failure points, reduce the circuit resistance, and reduce interconnect capacitance, which affects electrical performance. The need to reduce the IC package to fit end-user applications (e.g., Smart cards, palmtop computers, camcorders, and so on) is driving the new packaging designs that reduce size and overall profile. This reduction is offset by the need for handling larger amounts of parallel data lines, therefore driving the need to increase package input/output requirements with-more leads.

Advanced packaging designs are regularly introduced to solve packaging challenges. One such advanced package design is flip chip. Flip chip is a packaging method of mounting the active side of a chip (with the surface bonding pads) toward the substrate (i.e., upside down placement of the bumped die relative to the wirebonding approach—thus the reason for the term “flip” chip). It provides the shortest path from the chip devices to the substrate and low cost interconnection for high volume automated production. There is also a reduction in weight and profile since leadframes or plastic packages are often not used. Flip chip technology uses solder bumps—usually formed from tin/lead solder in a 5% Sn and 95% Pb ratio—to interconnect the chip bonding pads to the substrate.

There are several methods known to those skilled in the art for producing solder bumps on a semiconductor device. FIGS. 1A-1F illustrate a prior art method of forming a bump on a substrate of a semiconductor wafer. As shown in FIG. 1A, a semiconductor wafer 2 is provided having a base semiconductor substrate 4 with metal interconnect layers (not shown) overlying substrate 4 and a first passivation layer 8, which may be one or more layers, that extends partially over a bond pad or contact pad 6. Thereafter, a second passivation layer 10 is deposited over the first passivation layer 8. First passivation layer 8 and second passivation layer 10 are then patterned and etched by conventional photolithographic processes to leave an opening overlying contact pad 6 so that electrical contact to an external circuit may be made from the semiconductor wafer 2. Contact pad 6 may be made from any of a variety of metals, such as aluminum, aluminum alloys, copper, and copper alloys. Typically, a plurality of under bump metallurgy (UBM) layers are provided over the entire upper surface of semiconductor wafer 2 and over the upper surface of contact pad 6. The UBM layers may be composed of a plurality of individual layers of a variety of different metals and may be deposited by any of a variety of methods including electroless plating, sputtering, or electroplating. As shown in FIG. 1B, a first UBM layer 13 is deposited on semiconductor wafer 2 having a lowermost UBM layer of titanium 12 followed by an uppermost UBM layer of copper 14. As shown in FIG. 1C, a photoresist layer 20 is thereafter deposited over first UBM layer 13 and patterned to provide an opening 18 overlying contact pad 6 on semiconductor wafer 2. Thereafter, a second UBM layer 15 is deposited in opening 18. Second UBM layer 15 has a lowermost UBM layer of copper 17 and an uppermost UBM layer of nickel 16 for forming a solder bump thereover. An electrically conductive material (e.g. solder) may then be deposited in opening 18 and on top of the UBM layer 15 as shown in FIG. 1D to form a column of solder material 22. As shown in FIG. 1E, after removal of the photoresist layer 20, the UBM layers 15 and 13 are etched through by a reactive ion etch (RIE) process, for example, to the underlying second passivation layer 10 using the solder column 22 as an etching mask to protect the underlying UBM layers. The solder column 22 is then heated to reflow to form a solder bump 24 over the UBM layer 15 as shown in FIG. 1F.

In the formation of solder humps, the UBM layers must be able to withstand thermal and mechanical stresses placed upon the semiconductor wafer. Therefore, the quality of the UBM layers is critical to the mechanical integrity and therefore the reliability of the solder bump structure. One recurring problem with the prior art method of forming solder bump structures is that frequently, delaminations occur in the UBM layers. Referring back to FIG. 1F, in many cases, the delamination 26 occurs at the juncture of UBM layers, such as at UBM layer of titanium 12 and UBM layer of copper 14 and 17.

For these reasons and other reasons that will become apparent upon reading the following detailed description, there is a need for an improved method for forming solder bump structures in advanced IC packaging such as flip chip that avoids the shortcomings and deficiencies in the prior art methods of forming solder bump structures.

### SUMMARY OF THE INVENTION

The present invention is directed to methods for forming an improved bump structure on a semiconductor device. In one embodiment, a substrate is provided having at least one contact pad formed thereon. A first passivation layer is formed over the substrate, the first passivation layer having at least one opening therein exposing a portion of the contact pad. A first patterned and etched conductive metal layer is formed on the contact pad and above a portion of the first passivation layer. A second patterned and etched passivation layer is formed above the first passivation layer and a portion of the first conductive metal layer, wherein a portion of the ends of the first conductive metal layer is wedged between the first and second passivation layers. A second conductive metal layer is formed above the second passivation layer and the first conductive metal layer. A patterned and etched photoresist layer is then formed over a portion of the second passivation layer, the photoresist layer having an opening overlying the contact pad, and a solder material is deposited in the opening to form a solder column. The photoresist layer is thereafter removed and the second conductive metal layer is etched to the second passivation layer by using the solder column as an etching mask. The solder column is then reflown to create a solder bump.

Further scope of the applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the following detailed description and the accompanying drawings, which are given by way of illustration only, and thus are not limitative of the present invention, and in which:

FIGS. 1A-1F arc cross-sectional views of a semiconductor device depicting a prior art method of forming a solder bump structure.

FIGS. 2A-2F are cross-sectional views of a semiconductor device depicting a method of forming a solder bump structure according to one embodiment of the present invention.

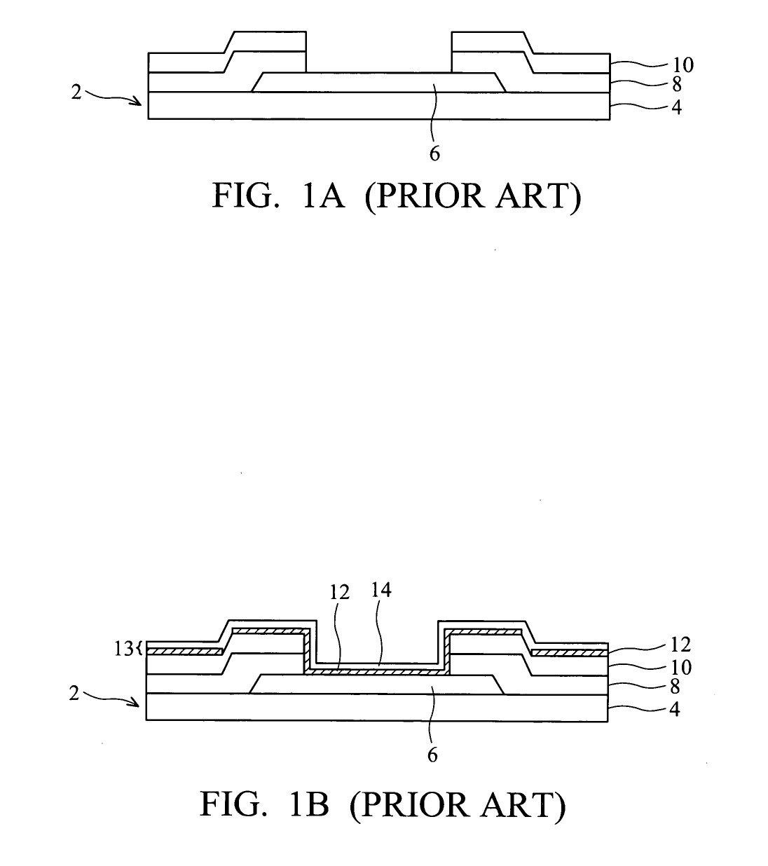

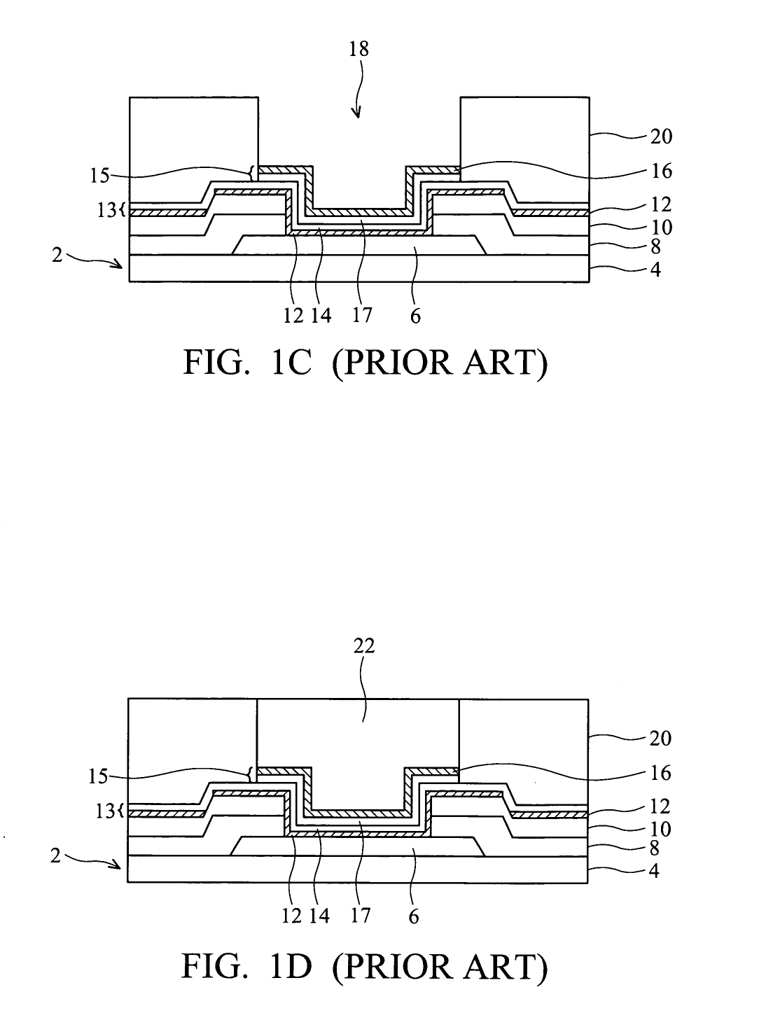

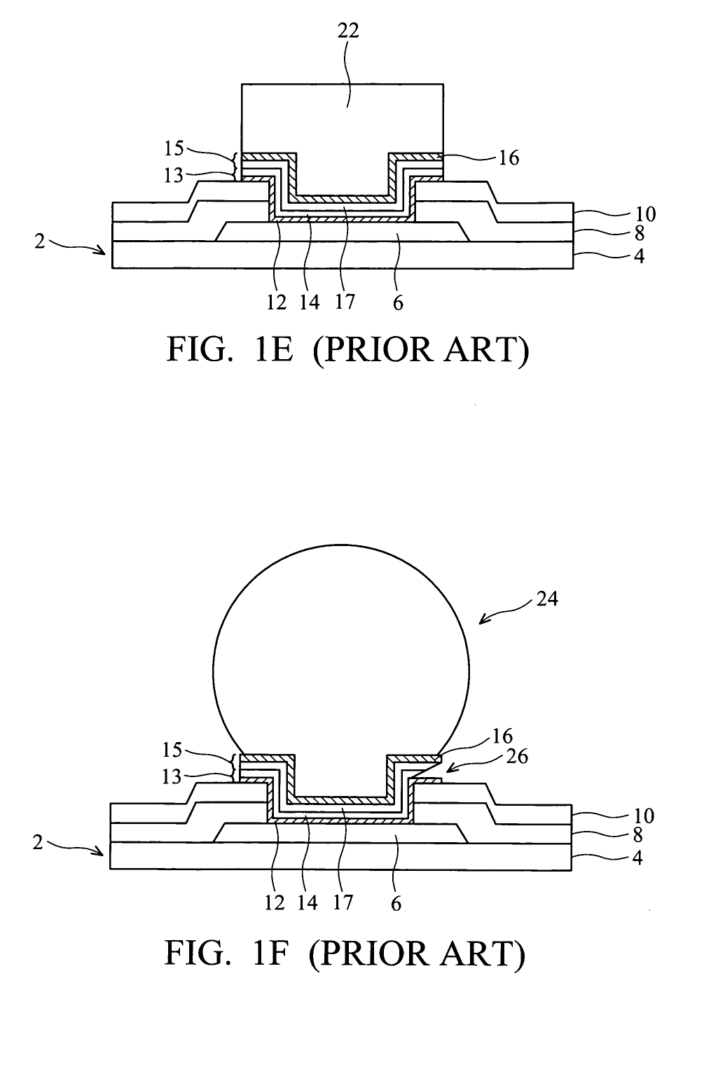

### DETAILED DESCRIPTION OF THE PREFERRED EMBODIMENTS

In the following description, numerous specific details are set forth to provide a thorough understanding of the present invention. However, one having an ordinary skill in the art will recognize that the invention can be practiced without these specific details. In some instances, well-known structures and processes have not been described in detail to avoid unnecessarily obscuring the present invention.

Reference will now be made in detail to the present preferred embodiments of the present invention, examples of which are illustrated in the accompanying drawings.

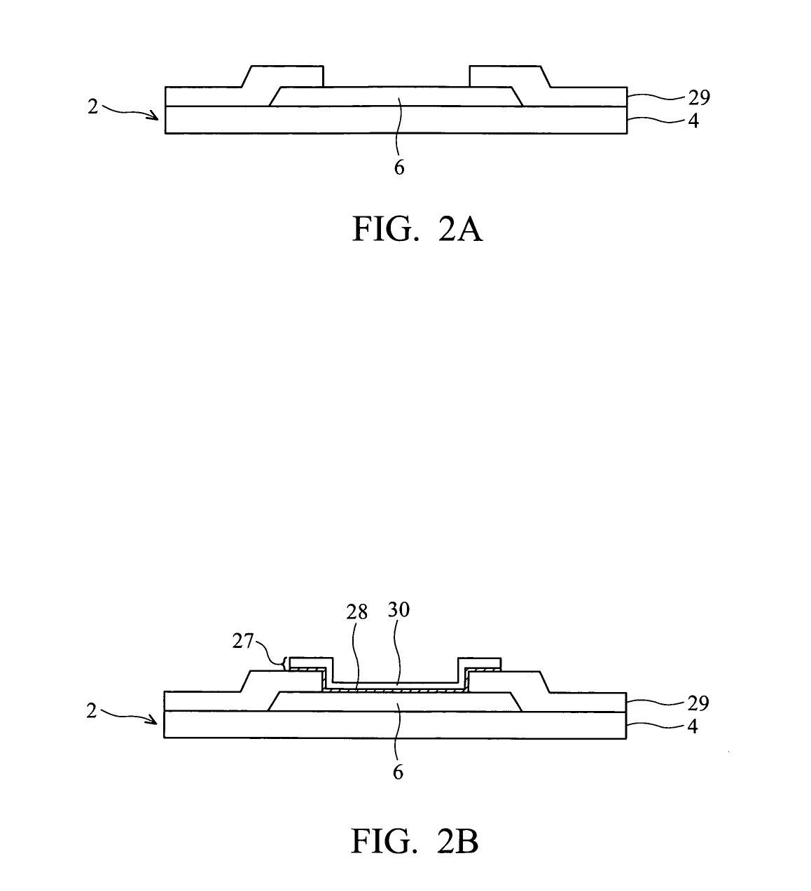

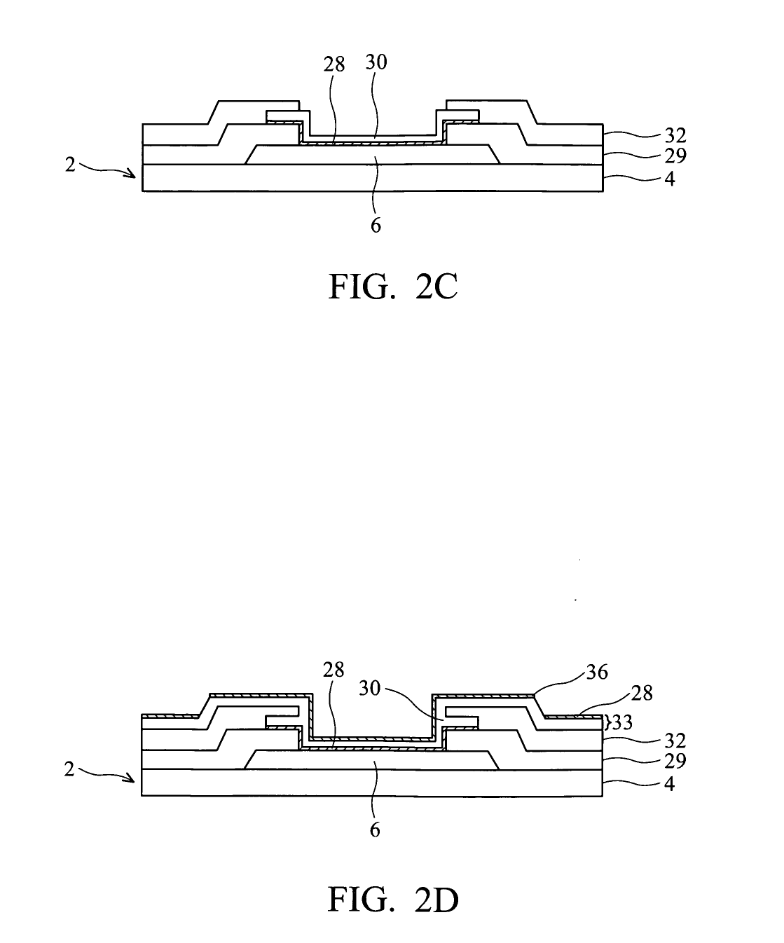

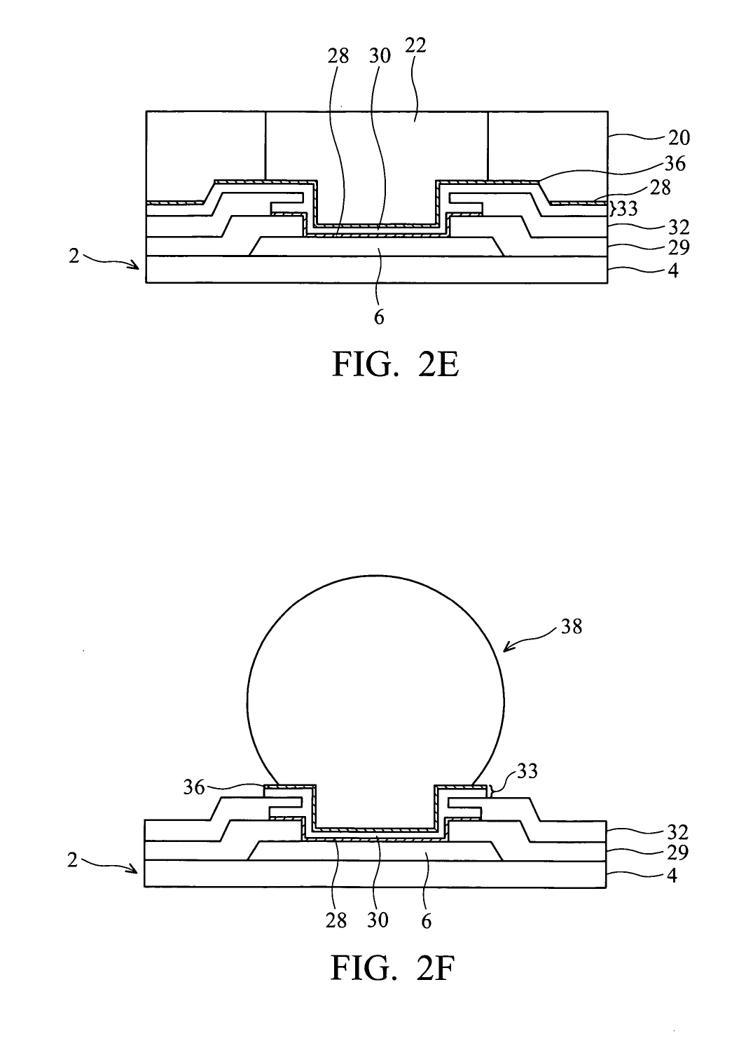

As shown in FIG. 2A, a cross-sectional view of a semiconductor device depicting a method of forming a solder bump structure according to one embodiment of the present invention is provided. A semiconductor wafer 2 is provided having a base semiconductor substrate 4 with metal interconnect layers (not shown) overlying substrate 4 and a first passivation layer 29, which may be one or more layers, that extends over a bond pad or contact pad 6 located on the upper surface of the semiconductor wafer 2. Substrate 4 is understood to include active and passive devices, conductive layers and dielectric layers and the type of the substrate is a design choice dependent on the fabrication process being employed. Following patterning and development by conventional photolithographic processes, first passivation layer 29 has all opening therein exposing a portion of contact pad 6. First passivation layer 29 may be comprised of a material such as for example, undoped silicate glass (USG), silicon nitride (SiN), silicon dioxide (SiO₂), and silicon oxynitride (SiON). In one embodiment, first passivation layer 29 is USG and has a thickness of from about 3,600 Angstroms to about 4,400 Angstroms. Contact pad 6 establishes electrical contact between the electrical interconnects in substrate 4 and a later to be formed overlying solder bump. Contact pad 6 may be formed by vapor deposition and may be comprised of any of a variety of metals, such as for example, aluminum, aluminum alloys, copper, and copper alloys.

Following the formation of first passivation layer 29 on substrate 4 exposing a portion of contact pad 6, a plurality of UBM (under bump metallurgy) layers are then deposited by conventional methods such as sputtering, vapor deposition, electroless plating, or electroplating over the surface of semiconductor wafer 2 including contact pad 6 to allow for better bonding and wetting of a later to be deposited solder material to the uppermost UBM layer. As shown in FIG. 2B, a first UBM layer 27 is deposited over the surface of semiconductor wafer 2, including contact pad 6 and first passivation layer 29. First UBM layer 27 may comprise of one or more layers and a variety of different metals, such as titanium (Ti), copper (Cu), and nickel (Ni), for example. In one embodiment of the present invention, first UBM layer 27 comprises of a lower UBM layer 28 of titanium (Ti) and an uppermost UBM layer 30 of copper (Cu). In one embodiment, first UBM layer 27 has a thickness of from about 5,400 Angstroms to about 6,600 Angstroms. Following patterning and etching by conventional photolithographic processes, the patterned and etched first UBM layer 27 is shown in FIG. 2B.

A second passivation layer 32 is deposited over semiconductor wafer 2, including first passivation layer 29 and first UBM layer 27. Second passivation layer 32 may be comprised of a material such as for example, silicon nitride (SiN), silicon dioxide (SiO₂), and silicon oxynitride (SiON). In one embodiment, second passivation layer 32 is SiN and has a thickness of from about 5,400 Angstroms to about 6,600 Angstroms. Following conventional photolithographic patterning and etching, the second passivation layer 32 is as shown in FIG. 2C. FIG. 2C shows that a portion of the ends of first UBM layer 27 is now wedged between the first passivation layer 29 and the second passivation layer 32. By wedging at least one UBM layer between at least two passivation layers, the solder bump structure of the present invention can be made more robust and therefore prevent the delamination among UBM layers, and in particularly the delamination of the uppermost UBM layer adjacent the solder bump and the UBM layer beneath the uppermost UBM layer. The amount of the ends of first UBM layer 27 that needs to be wedged between first and second passivation layers 29 and 32, respectively, is an amount sufficient to prevent the occurrence of delamination from any one of a number of UBM layers.

Referring now to FIG. 2D, a second UBM layer 33 is deposited over the surface of semiconductor wafer 2, including first UBM layer 27 and second passivation layer 32 by conventional methods such as sputtering, for example. Second UBM layer 33 may comprise of one or more layers and a variety of different metals. In one embodiment of the present invention, second UBM layer 33 comprises of a lower UBM layer of copper (Cu) and an upper UBM layer 36 of nickel (Ni). In one embodiment, second UBM layer 33 has a thickness of from about 30,000 Angstroms to about 130,000 Angstroms.

Following the deposition of second UBM layer 33 over semiconductor wafer 2, a photoresist layer 20 is thereafter deposited over second UBM layer 33 and patterned and developed to form an opening overlying contact pad 6 as shown in FIG. 2E. The photoresist layer 20 typically has a height of from about 10 to about 25 microns high. An electrically conductive material (solder material) may be deposited in the opening by evaporation, electroplating, or screen printing to form a column of solder 22. The electrically conductive material may be any of a variety of metals, metal alloys or metals and mixtures of other materials, but preferably, the electrically conductive material is a solder. The solder may be any of a variety of compositions and in one embodiment, the solder is in a 63 weight percent Sn, 37 weight percent Pb composition.

As shown in FIG. 2F, after the removal of photoresist layer 20, the second UBM layer 33 is etched through by reactive ion etch (RIE) process, for example, to the underlying second passivation layer 32 using the solder column 22 as an etching mask. The solder column 22 is then reflown by heating to form a solder bump 38 on the semiconductor wafer 2.

In the present invention, by wedging at least one UBM layer between at least two passivation layers, the solder bump structure of the invention can be made more robust and therefore prevent delaminations from occurring among the UBM layers, such as between the uppermost UBM layer adjacent the solder bump and the UBM layer beneath the uppermost UBM layer. The solder bump structures formed by the present invention avoid the reliability and IC performance problems associated with conventional methods of forming solder bump structures.

In the preceding detailed description, the present invention is described with reference to specifically exemplary embodiments thereof. It will, however, be evident that various modifications, structures, processes, and changes may be made thereto without departing from the broader spirit and scope of the present invention, as set forth in the claims. The specification and drawings are, accordingly, to be regarded as illustrative and not restrictive. It is understood that the present invention is capable of using various other combinations and environments and is capable of changes or modifications within the scope of the inventive concept as expressed herein.

1. A method for forming a bump structure on a semiconductor device, comprising:
providing a substrate having at least one contact pad formed thereon;
forming a first passivation layer over the substrate, the first passivation layer having at least one opening therein exposing a portion of the contact pad;
forming a first patterned and etched conductive metal layer on the contact pad and above a portion of the first passivation layer;
forming a second patterned and etched passivation layer above the first passivation layer and a portion of the first conductive metal layer, wherein a portion of the ends of the first conductive metal layer being wedged between the first and second passivation layers;
forming a second conductive metal layer above the second passivation layer and the first conductive metal layer;
forming a patterned and etched photoresist layer over a portion of the second passivation layer, wherein the photoresist layer having an opening overlying the contact pad, and the opening does not expose an interface of the first patterned and etched conductive metal layer and the second conductive metal layer; and
depositing a solder material in the opening, to form a solder column.

2. (canceled)

3. The method of claim 2, further comprising removing the photoresist layer and etching the second conductive metal layer to the second passivation layer by using the solder column as an etching mask.

4. The method of claim 3, further comprising reflowing the solder column to create a solder bump.

5. The method of claim 1, wherein the first passivation layer is a material selected from the group consisting of undoped silicate glass (USG), silicon nitride (SiN), silicon dioxide (SiO₂), and silicon oxynitride (SiON) and has a thickness of from about 3,600 Angstroms to about 4,400 Angstroms.

6. The method of claim 1, wherein the first conductive metal layer comprises a UBM (Under Sump Metallurgy) layer.

7. The method of claim 1, wherein the first conductive metal layer comprises a titanium layer and a copper layer.

8. The method of claim 1, wherein the first conductive metal layer has a thickness of from about 5,400 Angstroms to about 6,600 Angstroms.

9. The method of claim 1, wherein the second passivation layer is a material selected from the group consisting of silicon nitride (SiN), silicon dioxide (SiO₂), and silicon oxynitride (SiON) and has a thickness of from about 5,400 Angstroms to about 6,600 Angstroms.

10. The method of claim 1, wherein the second conductive metal layer comprises a UBM (Under Bump Metallurgy) layer.

11. The method of claim 1, wherein the second conductive metal layer comprises a copper layer and a nickel layer.

12. The method of claim 1, wherein the second conductive metal layer has a thickness of from about 30,000 Angstroms to about 130,000 Angstroms.

13. A bump structure on a semiconductor device, comprising:
a substrate having at least one contact pad formed thereon;
a first passivation layer formed over the substrate, the first passivation layer having at least one opening therein exposing a portion of the contact pad;
a first patterned and etched conductive metal layer formed on the contact pad and above a portion of the first passivation layer;
a second patterned and etched passivation layer formed above the first passivation layer and a portion of the first conductive metal layer, wherein a portion of the ends of the first conductive metal layer being wedged between the first and second passivation layers; and
a second patterned and etched conductive metal layer formed above a portion of the second passivation layer and above the first conductive metal layer, wherein an interface of the first patterned and etched conductive metal layer and the second patterned and etched conductive metal layer is not exposed.

14. The bump structure of claim 13 further comprising a layer of solder column provided above the second conductive metal layer, wherein the solder column is reflown to create a solder bump.

15. The bump structure of claim 13, wherein the first passivation layer is a material selected from the group consisting of undoped silicate glass (USG), silicon nitride (SiN), silicon dioxide (SiO₂), and silicon oxynitride (SiON) and has a thickness of from about 3,600 Angstroms to about 4,400 Angstroms.

16. The bump structure of claim 13, wherein the first conductive metal layer comprises a UBM (Under Bump Metallurgy) layer.

17. The bump structure of claim 13, wherein the first conductive metal layer comprises a titanium layer and a copper layer.

18. The bump structure of claim 13, wherein the first conductive metal layer has a thickness of from about 5,400 Angstroms to about 6,600 Angstroms.

19. The bump structure of claim 13, wherein the second passivation layer is a material selected from the group consisting of silicon nitride (SiN), silicon dioxide (SiO₂), and silicon oxynitride (SiON) and has a thickness of from about 5,400 Angstroms to about 6,600 Angstroms.

20. The bump structure of claim 13, wherein the second conductive metal layer comprises a UBM (Under Bump Metallurgy) layer.

21. The bump structure of claim 13, wherein the second conductive metal layer comprises a copper layer and a nickel layer.

22. The bump structure of claim 13, wherein the second conductive metal layer has a thickness of from about 30,000 Angstroms to about 130,000 Angstroms.
